(19) United States
(12) Patent Application Publication
(10) Pub. No.: US 2004/0168639 A1
(43) Pub. Date: Sep. 2, 2004

(54) Method and device for short-term thermal-treatment of flat objects

(76) Inventor: Gerhard Karl Strauch, Aachen (DE)

Correspondence Address: ST. ONGE STEWARD JOHNSTON & REENS, LLC, 986 BEDFORD STREET, STAMFORD, CT, 06905-5619, US

(21) Appl. No.: 10/725,914

(22) Filed: Dec. 1, 2003

Related U.S. Application Data
(63) Continuation of application No. PCT/EP02/05767, filed on May 25, 2002.

(30) Foreign Application Priority Data
Jun. 8, 2001 (DE) 101 28 190.0
Jul. 5, 2001 (DE) 101 32 709.9

(51) Int. Cl. C23C 16/00

(52) U.S. Cl. 118/724; 118/725

(57) ABSTRACT

The invention relates to a method and a device for the thermal treatment, especially short-term, of flat objects in particular, such as semi-conductor, glass or metal substrates. Heat is, at least in part, supplied to or taken away from both sides of said substrates by means of thermal conduction via a thermal conduction medium. The invention aims to improve the method and device so that they can be used effectively. To this end, a mixture consisting of two gases, differing greatly in their thermal conductivity, is used as a thermal conductive medium. The mixture on both sides of the substrate is individually adjusted so that the respective surface temperature is time-controlled by taking the respective heat exchange due to heat radiation into account.

This application is a continuation of pending International Patent Application No. PCT/EP02/05767 filed May 25, 2002, which designates the United States and claims priority of pending German Application Nos. 101 28 190.0 filed Jun. 8, 2001 and 101 32 709.9 filed Jul. 5, 2001.

### FIELD OF THE INVENTION

The invention relates to an apparatus and a method for the in particular short-duration thermal treatment of in particular flat objects, such as semiconductor, glass or metal substrates, having temperature-influencing devices disposed on both sides of the substrate surfaces for heat exchange with the substrate, which heat exchange takes place at least in part through heat conduction via a heat-conducting medium.

When producing components from a semiconductor material, it is often necessary for the substrates or the ready-patterned substrates which have been coated or pretreated in some other way, for example by implantation steps, to be subjected to a further heat treatment. This is carried out using a process referred to as rapid thermal processing (RTP). The two opposite wide side faces of the substrate may have different surface emissivities. For the substrates to be heated uniformly, i.e. without internal temperature gradients, the radiation powers with which the two sides are heated have to be matched to the different surface emissivities. The heating is effected, for example, by means of infrared radiation or via heat conduction, which takes place via a medium, for example a gas, which is in contact with the substrate surface. The cooling rate is also dependent on the surface emmisivity. Therefore, suitable measures have to be taken to ensure that the temperature decreases or increases uniformly on both surfaces. The heating and cooling are to take place quickly. The surface emmisivity may change during the RTP process. The emmisivity is a measure of the extent to which the substrate radiates heat or absorbs radiant heat. Since the removal of heat from the substrate, in particular at high temperatures, is highly dependent on the emissivity of the corresponding surface, and the emissivities of the front and back surfaces are not generally identical, there is a fundamental risk of the substrate being thermally bent as it is cooled or heated. The larger the substrate, the more significant this phenomenon becomes. The substrates, which are in the form of circular wafers, may have diameters of, for example, 300 mm. It is known in the prior art to counteract this phenomenon by controlling the heating of the two wide sides of the substrate separately. This requires highly accurate, emissivity-compensated temperature measurement. This has the drawback that expensive measurement and control fittings, which may have a limited accuracy, are used. Moreover, with a structure of this type it is impossible to completely avoid a temperature gradient from the front surface to the back surface, for example during cooling.

The invention is based on the object of developing the method and apparatus of the generic type in a manner which is advantageous for their use.

The object is achieved by the method specified in Claim 1 and the apparatus specified in Claim 2 in which the heat-conducting medium is a mixture of at least two gases with very different thermal conductivities, and the mixture can be set individually on the two wide sides of the substrate. The mixture is set individually in such a manner that the prevailing surface temperature is time-controlled taking account of the prevailing total heat exchange via thermal radiation. In particular, the profile of the temperature during heating or cooling and its respective value on the two substrate wide sides are identical. Increased exchange via thermal radiation can be compensated for by using a gas mixture ratio in which the gas of poor thermal conductivity is dominant.

A low level of heat exchange via heat radiation is correspondingly compensated for by the use of a gas mixture in which the gas with a high thermal conductivity is dominant. However, according to the invention it is also possible for the heat exchange on the two sides to be kept at different levels, so that during heating or cooling of the substrate a temperature gradient, which in particular is kept the same throughout the entire heat treatment time or heat exchange time, is formed within the substrate from the front surface to the back surface. The two gas mixtures are controlled separately. The gas mixtures can be selected from inert gases with a high purity and with different specific thermal conductances. Control can be effected by means of simple mass flow controllers. Examples of gases with a high thermal conductivity are hydrogen or helium. Gases with a low thermal conductivity are nitrogen or argon. The mixture is introduced into the process chamber with a total pressure and ratio above and/or below the substrate which are such that sufficient heat is exchanged with the substrate as a result of the thermal conductivity. The temperature-influencing devices, in particular those used to cool the substrate, may therefore be disposed a short distance above or below the substrate. If the substrate is in a vertical position in the process chamber, the two temperature-influencing devices are then horizontally next to the substrate, the arrangement and configuration of the temperature-influencing devices being selected in such a way that the heat transfer from or to the substrate takes place uniformly over the entire substrate surface, in such a manner that no significant temperature differences are established over the substrate surfaces. It is preferable for the temperature-influencing devices and the mixtures of the two gases to be set in such a way that, taking account of the heat transfer by means of thermal radiation, on both sides the amounts of heat exchanged per unit time are such that the internal temperature gradient from the front surface to the back surface of the substrate is zero. The mixture preferably flows through a gap space located above and/or below the substrate. This continuous exchange of gas means that it is possible to rapidly change the gas mixture. Changing the mixture ratio during heat exchange makes it possible to control the heat flux by means of the variable thermal conductivity. It is also possible to deliberately set the heat balances to be different for each surface, if the thermal stress involved is accepted. This too can be effected by trimming the gas mixture. It is preferable for only a relatively thin gas gap to be located on the underside of the substrate. The gas volume is then sufficiently thin to form a gas cushion on which the substrate rests. The gas cushion may be formed by the moderate gas mixture flow into the volume. The mass of gas which flows in is kept at a low level, such that no significant heat is dissipated via the gas mass flow. The substrate can not only be mounted in a floating position, and isostatically and isothermally at the same time, but can also be driven in rotation by the gas stream.

### BRIEF DESCRIPTION OF THE DRAWINGS

Exemplary embodiments of the invention are explained below with reference to the appended drawings, in which:

FIG. 1 shows a highly diagrammatic illustration of a first exemplary embodiment of the invention with temperature-influencing devices disposed above and below the substrate,

FIG. 2 shows a second exemplary embodiment of the invention, in which the substrate floats freely on a gas cushion, and

FIG. 3 shows the temperature profile of the temperatures T1, T2 of the two substrate surfaces during heating or cooling.

### DETAILED DESCRIPTION OF THE DRAWINGS

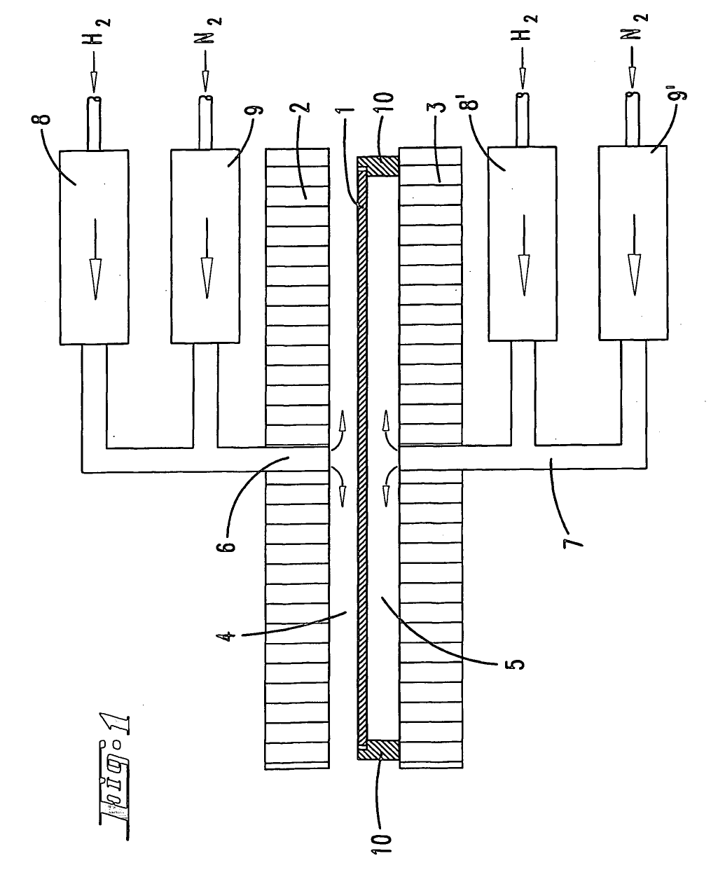

In the exemplary embodiment shown in FIG. 1, the substrate 1 is resting on bearing skirts 10. These bearing skirts 10 cause the substrate 1 to adopt a gap spacing 5 from a lower temperature-influencing device 3. This temperature-influencing device 3 may be a heat sink or a heat source. It is also possible for the temperature-influencing device 2 disposed above the substrate, which is likewise a temperature-influencing device 2 disposed at a spacing from the substrate 1, via a gap space 4, to be a heat sink or a heat source. The temperature-influencing devices 2 and 3 may also perform both functions. By way of example, they may form cooled surfaces and at another time may have the effect of radiating infrared radiation in order on the one hand to cool the substrate by dissipating heat and on the other hand to heat the substrate by supplying heat.

Supply lines 6, 7 lead through each of the temperature-influencing devices 2, 3. The supply lines 6, 7 may also be configured differently. Their purpose is to introduce a gas mixture, which consists, for example, of helium and argon or hydrogen and nitrogen, into the two gap spaces 4, 5.

An individual gas mixture comprising hydrogen and nitrogen or helium and argon is continuously introduced into each of the two gap spaces 4, 5. The total pressure of the two gas mixtures is substantially identical. It is sufficiently high for the gases in the gap space 4, 5 to have a head-conducting action. The gap width of the gap spaces 4, 5 is also selected suitably on this basis.

Hydrogen and nitrogen are fed into the respective supply line 6, 7 by means of individual mass flow controllers 8, 9.

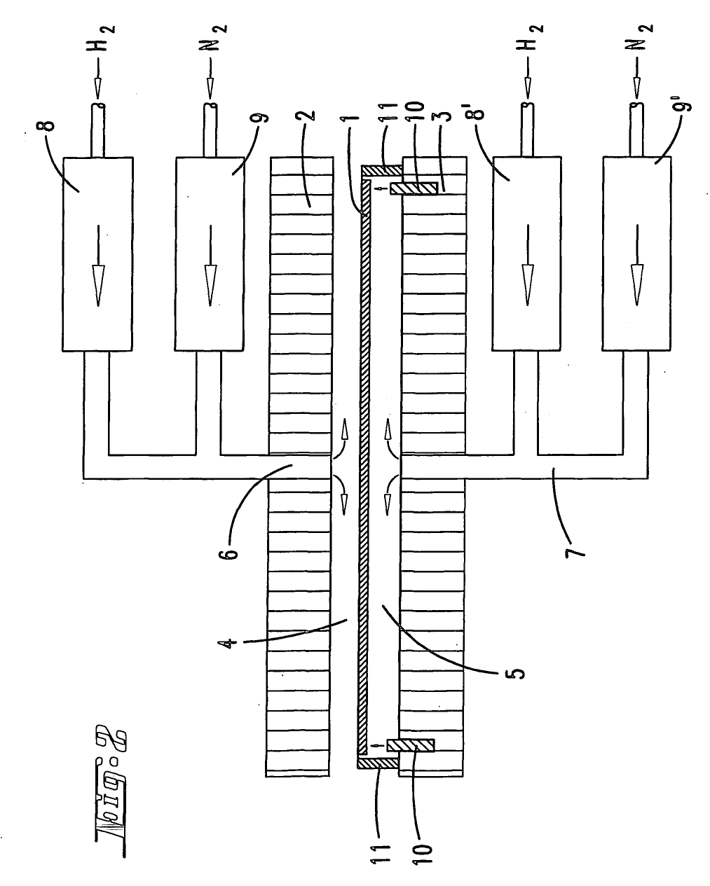

In the exemplary embodiment illustrated in FIG. 2, the substrate 1, during the heat exchange, is mounted not on skirts 10 which support the edge of the substrate 1, but rather rests floating freely on a gas cushion which is maintained by the gas mixture which has been introduced into the gap space 5 through the supply line 7. By way of example, in this case it is only necessary to provide supporting webs 11 which hold the substrate 1 in position. However, even these are not absolutely imperative. The substrate may also rest in a self-centering manner on the gas cushion.

In addition, optional support skirts 10, which can lift the substrate 1 in order for the process chamber to be loaded or unloaded, are illustrated in FIG. 2.

The apparatus according to the invention functions as follows: the substrate 1 may have different thermal emissivities on its two substrate surfaces. The result of this is that for the same radiation power from the temperature-influencing devices 2, 3 performing a heating function, the extent to which the two opposite substrate wide side surfaces are heated may differ. At any rate, the flow of heat into the substrate via thermal radiation is different. Similar effects occur during cooling of the substrate 1. The different emissivities cause different quantities of heat to be released on both sides during the thermal radiation. The result of this is that during heating or cooling of the substrate the substrate surfaces may be at different temperatures. This internal temperature gradient can lead to undesirable deformation.

A gas mixture comprising hydrogen and nitrogen is introduced into the gap spaces 4, 5 above and below the substrate. On the substrate side which has a high emissivity, this gas mixture has a high nitrogen content. The gas mixture then has a low thermal conductivity. On the side on which the emissivity is lower, the gas mixture 4 has a higher hydrogen content, so that the gas mixture has a higher thermal conductivity there. The heat which is radiated out or supplied by radiation to a lesser extent on one side on account of the different thermal radiation is compensated for by a corresponding dissipation of heat or supply of heat via heat conduction, so that the surface temperatures remain substantially the same on the two substrate wide side surfaces during the heat exchange. In this context, it may be necessary for the gas mixture which can be set by means of the mass flow controllers 8, 9 to be altered during the heating or cooling process.

In the exemplary embodiment illustrated in FIG. 2, a gas cushion on which the substrate 1 floats freely is built up by means of the gas flow provided by the mass flow controllers 8′, 9′. Heat exchange via surface contact with holding skirts or the like is thereby avoided. The nozzle positioned at the end of the supply line 7 may be directed in such a way that a rotary momentum is transmitted to the substrate 1. In particular, it is preferable for a multiplicity of nozzles to be provided both above and below the substrate 1. The substrate 1 can even be driven in rotation by means of these nozzles.

It may be advantageous in certain applications for the heat balance on the two surfaces to be deliberately set at different levels. This may be desirable in particular if it is desired to deliberately introduce thermal stresses by means of temperature differences between the front and back surfaces.

During the process, the temperatures of the two surfaces can be measured optically. A temperature drift can be counteracted by suitable control measures involving changing the composition of the gas mixture.

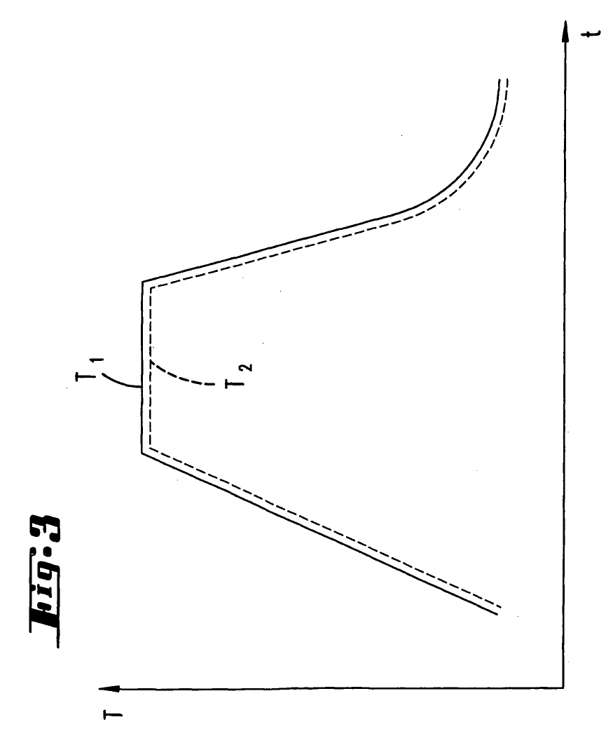

FIG. 3 shows the profile of the temperature T₁ on one substrate surface and the temperature T₂ on the other substrate surface during heating, heat treatment and cooling. In this figure, the profile of the temperature T₁ is illustrated by a continuous line, and the profile of the temperature T₂ is illustrated by means of a dashed line. The two lines are virtually congruent. This is a consequence of the optimized trimming of the supply of heat to the two substrate wide sides by means of thermal radiation, on the one hand, and controlled heat conduction, on the other hand. The cooling process also takes place by heat being dissipated by radiation and conduction. In this case too, the conduction of heat is controlled.

All features disclosed are (inherently) pertinent to the invention. The disclosure content of the associated/appended priority documents (copy of the prior application) is hereby incorporated in its entirety in the disclosure of the application, partly with a view to incorporating features of these documents in claims of the present application.

What is claimed is:

1. Process for the in particular short-duration thermal treatment of in particular flat objects, such as semiconductor, glass or metal substrates, to or from which heat is supplied or dissipated on both sides, at least partially through heat conduction via a heat-conducting medium, characterized in that the heat-conducting medium used is a mixture of at least two gases with very different thermal conductivities, and the mixture is set individually on the two sides of the substrate (1) in such a manner that the respective surface temperature is time-controlled taking account of the respective heat exchange via thermal radiation.

2. Apparatus for the in particular short-duration thermal treatment of in particular flat objects, such as semiconductor, glass or metal substrates, having temperature-influencing devices (2, 3) disposed on both sides of the substrate surfaces for heat exchange with the substrate (1), which heat exchange takes place at least in part through heat conduction via a heat-conducting medium, characterized in that the heat-conducting medium is a mixture of at least two gases with very different thermal conductivities, and the mixture can be set individually on the two sides of the substrate.

3. Method or apparatus according to one or more of the preceding claims, characterized in that the temperature is the same on both sides during the temperature-influencing action.

4. Method or apparatus according to one or more of the preceding claims, characterized in that the temperature is different on the two sides during the temperature-influencing action.

5. Method or apparatus according to one or more of the preceding claims, characterized in that the gases are hydrogen and nitrogen or helium and argon.

6. Method or apparatus according to one or more of the preceding claims, characterized by a continuous flow of gas into a gap space (4, 5) between temperature-influencing device (2, 3) and substrate (1).

7. Method or apparatus according to one or more of the preceding claims, characterized in that the gas flow is controlled by means of mass flow controllers (8, 9; 8′, 9′).

8. Method or apparatus according to one or more of the preceding claims, characterized in that the substrate (1) is mounted floating freely on a gas cushion formed by the gas stream associated with the underside of the substrate.

9. Method or apparatus according to one or more of the preceding claims, characterized in that the substrate (1) is driven in rotation, floating freely, by the gas stream which forms the heat-conducting medium.

10. Method or apparatus according to one or more of the preceding claims, characterized in that the temperature control involves dissipation of heat or supply of heat.

11. Method or apparatus according to one or more of the preceding claims, characterized in that the gas composition or gas pressure changes during the heat exchange over the course of time.

12. Method or apparatus according to one or more of the preceding claims, characterized in that the mass flow of the thermally conducting medium into the gap spaces (4, 5) is so slight that the quantity of heat which is supplied or dissipated via the gas mass flow is significantly less than the heat which is dissipated or supplied via heat conduction.
